(19) United States
(12) Patent Application Publication
(10) Pub. No.: US 2010/0236823 A1
(43) Pub. Date: Sep. 23, 2010

(54) RING OF POWER VIA

(75) Inventors: LIEN-FEN HU, SUNNYVALE, CA (US); JORGE E. MARTINEZ-VARGAS, JR., SAN FRANCISCO, CA (US); SAMUEL M. LEE, SAN JOSE, CA (US); KARL A. SAUTER, PLEASANTON, CA (US); AARON MENDELSOHN, DANVILLE, CA (US)

Correspondence Address: MARSH FISCHMANN & BREYFOGLE LLP;(Oracle formerly d/b/a Sun Microsystems), 8055 East Tufts Avenue, Suite 450, Denver, CO, 80237, US

(73) Assignee: SUN MICROSYSTEMS, INC., Santa Clara, CA (US)

(21) Appl. No.: 12/406,850

(22) Filed: Mar. 18, 2009

(51) Int. Cl. H05K 1/11; H05K 3/00

(52) U.S. Cl. 174/262; 29/846

(57) ABSTRACT

Systems and methods for providing plated through-holes (PTH) in PCBs, which advantageously allow improved soldering capabilities, are described herein. Such systems and methods are achieved by reducing the heat sinking effects of PTHs by providing one or more vias surrounding the PTHs to provide an electrical connection between the PTH and the internal and bottom conductive layers of a PCB. In this regard, the PTHs are spaced apart from at least one of the internal conductive layers (e.g., ground or power layers), so the heat sinking effects are reduced. This feature enables molten solder to substantially fill the entire PTH before freezing, thereby improving the mechanical and electrical connection between an electrical component and the PCB.

### BACKGROUND OF THE INVENTION

Printed circuit boards, or PCBs, are generally used to mechanically support and electrically connect electronic components using conductive pathways, or traces, etched from copper sheets laminated onto a non-conductive substrate. A PCB populated with electronic components is referred to as a printed circuit assembly (PCA), also known as a printed circuit board assembly (PCBA). PCBs are generally rugged, inexpensive, and can be highly reliable. They require much more layout effort and higher initial cost than either wire-wrapped or point-to-point constructed circuits, but are much cheaper and faster for high-volume production. Some PCBs have trace layers inside the PCB and are called multi-layer PCBs, and may be formed by bonding together separately etched thin boards. Some multi-layer PCBs may include several layers (e.g., 4 layers, 12 layers, 24 layers, or more).

Holes are typically drilled through a PCB with tiny drill bits (e.g., made of solid tungsten carbide) in order to connect components to different layers of the PCB. The drilling may be performed by automated drilling machines, with the placement of the holes controlled by a drill tape or a computer generated drill file. The drill file describes the location and size of each hole to be drilled in the PCB. These holes are often filled with conductive annular rings to create vias, which allow the electrical and thermal connection of conductors on opposite sides of a PCB.

It is also possible with controlled-depth drilling, laser drilling, or by pre-drilling the individual sheets of the PCB before lamination, to produce holes that connect only some of the copper layers, rather than passing through the entire board. These holes are called “blind vias” when they connect an internal copper layer to an outer layer, or “buried vias” when they connect two or more internal copper layers and no outer layers. The walls of the vias, for boards with 2 or more layers, are generally plated with copper to form plated-through-holes (PTH) that electrically connect the conducting layers of the PCB.

After the printed circuit board (PCB) is completed, electronic components must be attached to the PCB to form a functional PCBA. In through-hole construction, electronic component leads are inserted in PTHs in the PCB. In surface-mount technology (SMT) construction, the components are placed on pads or lands on the outer surfaces of the PCB. In both kinds of construction, component leads are electrically and mechanically fixed to the PCB with molten metal solder.

Through-hole technology, also spelled “thru-hole”, refers to the mounting scheme used for pin-through-hole electronic components that involves the use of pins on the components that are inserted into copper PTH drilled in printed circuit boards (PCB) and soldered to pads on the opposite side. From the second generation of computers in the 1950s until surface-mount technology became popular in the late 1980s, every component on a typical PCB was a through-hole component. While through-hole mounting provides strong electrical and mechanical bonds when compared to surface-mount technology techniques, the additional drilling required makes the boards more expensive to produce. They also limit the available routing area for signal traces on layers immediately below the top layer on multilayer boards since the holes must pass through all layers to the opposite side. To that end, through-hole mounting techniques are now usually reserved for bulkier components such as electrolytic capacitors or semiconductors in larger packages that require the additional mounting strength provided by PTH technology.

PTH electronic components may be attached to a PCB using a soldering technique referred to as wave soldering. Wave soldering is a large-scale soldering process by which electronic components are soldered to a printed circuit board (PCB) to form an electronic assembly. The name is derived from the use of waves of molten solder to attach metal components to the PCB. The process uses a tank to hold a quantity of molten solder, and the components are inserted into or placed on the PCB and the loaded PCB is passed across a pumped wave or fountain of solder. The solder “wets” the exposed metallic areas of the board (e.g., those not protected with solder mask, a protective coating that prevents the solder from bridging between connections), creating a reliable mechanical and electrical connection. The process is much faster and can create a higher quality product than manual soldering of components. Wave soldering is used for both through-hole printed circuit assemblies and surface mount assemblies.

While there are many types of wave solder machines, the basic components and principles of these machines are generally the same. A standard wave solder machine includes three zones: the fluxing zone, the preheating zone, and the soldering zone. An additional fourth zone, a cleaning zone, may also be used depending on the type of flux applied.

When a PCB enters the fluxing zone, a fluxer applies flux to the underside of the board. Two types of fluxers are used: a spray fluxer and a foam fluxer. For either flux application method, precise control of flux quantities is required. Too little flux will cause poor joints, while too much flux may cause cosmetic or other problems. Also, as can be appreciated, the types of flux may affect the end result.

The PCB will then enter the preheating zone. The preheating zone consists of convection heaters, which blow hot air onto the PCB to increase its temperature. Generally, preheating is necessary to activate the flux, and to remove any flux carrier solvents. Preheating is also necessary to prevent thermal shock, which may occur when a PCB is suddenly exposed to the high temperature of the molten solder wave.

The tank of molten solder has a pattern of standing waves (or, in some cases, intermittent waves) on its surface. When the PCB is moved over this tank, the solder waves contact the bottom of the board, and stick to the solder pads and component leads by surface tension. For the pins of PTH components, molten solder fills the holes around the pins by capillary action. Precise control of wave height is required to ensure solder is applied to all areas but does not splash to the top of the board or other undesired areas. This process is sometimes performed in an inert gas Nitrogen (N₂) atmosphere to increase the quality of the joints.

As the thickness of a PCB increases (e.g., above 100 mils, 150 mils, 200 mils, or more), and the mass of copper sheets increases (e.g., above 0.5 oz, 1.0 oz, 1.5 oz, 2.0 oz, or more), it may become more difficult to successfully fill the pin holes during the soldering process. One cause of the increased difficulty is that the molten solder tends to cool (“freeze”) prematurely before it has traveled from the bottom of the PCB to the top. This problem can be further exaggerated in pin holes that are used for ground and power connections. The reason for this is that a multilayered PCB may include several ground or power layers (e.g., 4 layers, 8 layers, 12 layers, or more) that include large sheets of copper. The multiple layers of copper sheets may conduct heat away from the molten solder (i.e., act as heat sinks), causing the solder to freeze prematurely, and causing the pin hole to be only partially filled with solder (e.g., 75% filled, 50% filled, or less). When the pin hole is only partially filled with solder, the mechanical and electrical integrity of the solder connection may be significantly reduced or may even be ineffective. In this regard, standards have been set to require a minimum amount of solder that fills a through hole for various components. For example, the IPC requires solder to fill at least 75% of the through hole for a signal pin, and at least 50% of the through hole for a ground or power pin.

FIGS. 1 and 2 illustrate top and cross-sectional views of a PCB 100 that includes PTH components. The PCB 100 is configured with a resistor 104 and an integrated circuit 106. The PCB 100 includes a plurality of plated through-holes (e.g., PTH 108 and 110) that may be used to couple electronic components (e.g., the resistor 104 and the integrated circuit 106) from the top layer 102 (or top conductive layer 108 shown in FIG. 2) of the PCB 100 to a conductor (not shown in FIG. 1) on the bottom surface of the PCB 100. The PCB 100 may also include a plurality of metal traces (e.g., a copper trace 111) that are operative to couple different components of the PCB 100 together.

FIG. 2 illustrates a cross-sectional view of a portion of the PCB 100 shown in FIG. 1 cut at the line 2-2. As shown, the PCB 100 includes a plurality of dielectric layers 102, 116, 120, 122, 126, 128, and 132. The PCB 100 also includes a plurality of conductive layers 108, 114a-c, 118, 124, 130, and 134 disposed between the dielectric layers (e.g., the conductive and dielectric layers alternate). In the example shown, the resistor 104 is coupled to the conductive layers 108 and 134: (e.g., ground layers or power layers) at the bottom of the PCB 100 by soldering a pin 105 of the resistor 104 to the PCB 100 using a PTH 103 partially filled with solder. Further, the resistor 104 is coupled to other internal conductive layers 114a-114c, which are the same type of layer as the layers 108 and 134 (e.g., ground layers or power layers).

As shown, to mechanically and electrically couple the resistor 104 to the PCB 100, solder 107 is used to connect the pin 105 to the PTH 103. Thus, the pin 105 is coupled via the solder 107 and the PTH 103 to the conductive layers 108, 114a-c, and 134. It is noted that the conductive layers 118, 124, and 130 do not contact the PTH 103 and are therefore not connected to the pin 105. In this regard, the layers 118, 124, and 130 may include signal layers, ground layers, or power layers that are connected to other components.

As shown, the solder 107 only partially fills the opening of the PTH 103. This may be due to the heat sinking effects caused by the ground or power layers 114a-c and 134 that are coupled to the PTH 103. That is, during the soldering process, molten solder 107 fills the opening of the PTH 108 from the bottom to the top via capillary action, losing heat in the process. If the molten solder 107 cools too rapidly, it may freeze prematurely, causing the opening in the PTH 103 to be only partially filled as shown. Since the PTH 103 is coupled to potentially large sheets of copper (e.g., the ground or power layers 114a-c) which have a high heat transfer coefficient, the heat of the molten solder 107 is dissipated rapidly through these electrical and heat conducting layers;

### SUMMARY OF THE INVENTION

It is against this background that the “ring of power” via described herein has been invented. The present invention addresses the above problems by providing methods and systems for providing plated through-holes (PTH) in PCBs, which advantageously allow improved soldering capabilities. Such methods and systems are achieved by reducing the heat sinking effects of PTHs by providing one or more vias surrounding the PTHs to provide an electrical connection between the PTH and the bottom layer of a PCB. In this regard, the PTHs do not directly contact all of the internal ground or power layers, so the heat sinking or heat transfer effects are reduced. This feature enables molten solder to fill substantially the entire PTH before freezing. Further, one or more of the surrounding vias may be coupled to some or all of the ground or power layers without substantially increasing the heat sinking or transfer effects of the PTH. Various features and embodiments of the present invention are described in detail below.

According to a first aspect of the present invention, a multi-layer printed circuit board (PCB) is provided. The PCB includes a plurality of conductive layers with dielectric material disposed therebetween. Further, the PCB includes a through-hole that extends through the PCB, and a via, spaced apart from the through-hole, electrically coupled to one or more internal conductive layers of the plurality of conductive layers. Additionally, the through-hole is electrically coupled to the via, and the through-hole is spaced apart from at least one of the one or more internal conductive layers.

According to a second aspect of the present invention, a method of manufacturing a PCB is provided. The method includes providing a multi-layer PCB that includes a plurality of conductive layers with dielectric material disposed therebetween. The method also includes generating a through-hole that extends through the PCB, and generating a via, spaced apart from the through-hole, that is electrically coupled to one or more internal conductive layers of the plurality of conductive layers. Further, the through-hole is electrically coupled to the one or more vias, and the through-hole is spaced apart from at least one of the one or more internal conductive layers.

According to a third aspect of the present invention, a method for mechanically coupling an electrical component to a multi-layer PCB is provided. The method includes providing a multi-layer PCB that includes a plurality of conductive layers with dielectric material disposed therebetween, a through-hole that extends through the PCB, and a via, spaced apart from the through-hole, electrically coupled to one or more internal conductive layers of the plurality of conductive layers. The through-hole of the PCB is electrically coupled to the via of the PCB, and the through-hole is spaced apart from at least one of the one or more internal conductive layers. The method further includes providing an electrical component that includes a pin, and positioning the pin of the electrical component into the through-hole of the PCB. Additionally, the method includes soldering the pin to the through-hole to form a secure mechanical and electrical connection, wherein the solder substantially fills the through-hole.

Various features and refinements to the above-noted embodiments are also provided. For example, the multi-layer PCB may include a conductive surface land that couples the through-hole to one or more vias. As another example, the through-hole and/or the one or more vias may be plated with copper, or another conductive material. Further, the one or more internal layers may include ground layers, power layers, or signal layers.

In addition to the above, the size and number of the through-hole and the vias may be varied. For example the number of vias may be one, two, four, eight, or more. Further, the diameter of the vias may be substantially the same as the diameter of the through-holes, or different. As an example, in one embodiment, the diameter of the through-hole is about 60 to 100 mils, wherein the diameter of the one or more vias is about. 10-25 mils. Additionally, the through-hole may be spaced apart from one internal conductive layer that is coupled to a via, or more than one internal conductive layer.

In addition to the exemplary aspects and embodiments described above, further aspects and embodiments will become apparent by reference to the drawings and by study of the following descriptions.

### BRIEF DESCRIPTION OF THE DRAWINGS

FIG. 1 illustrates a prior art PCB configured with various electronic components.

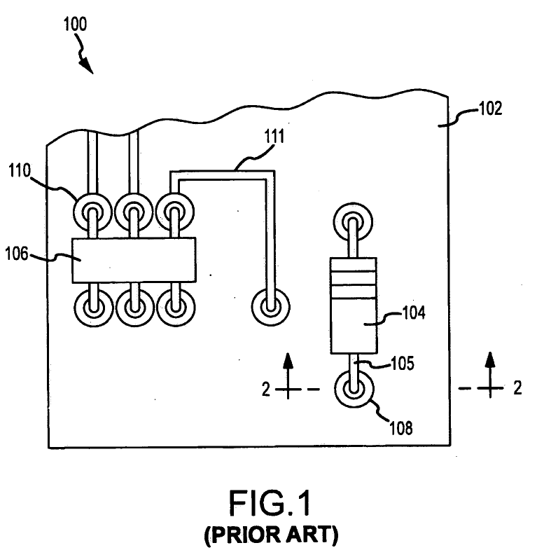

FIG. 2 illustrates the solder connection between a plated through-hole of a PCB and a resistor.

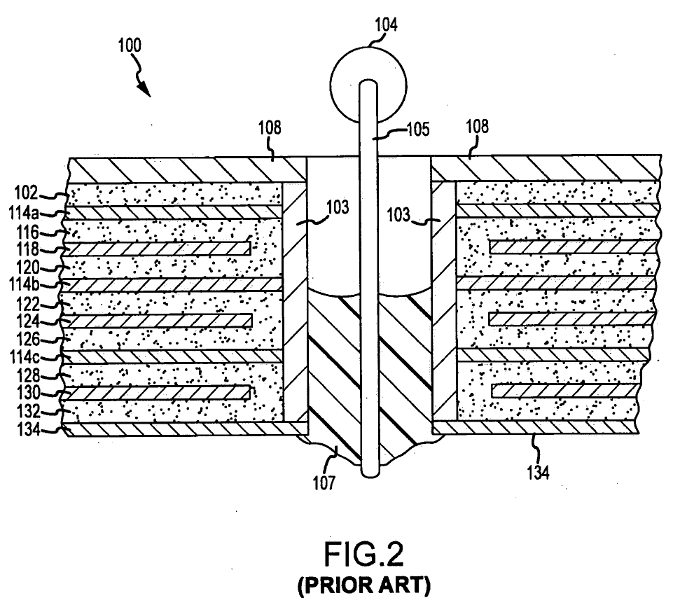

FIGS. 3a-3c illustrate various embodiments of an exemplary “ring of power” via of the present invention.

FIG. 4 illustrates a cross-sectional view of an exemplary “ring of power” via of the present invention.

FIG. 5 illustrates a perspective cross-sectional view of an exemplary “ring of power” via of the present invention.

FIGS. 6a-6c illustrate various electronic components that include pins that may be coupled to a PCB using a “ring of power” via of the present invention.

FIG. 7 illustrates a cross-sectional view of another exemplary “ring of power” via of the present invention.

### DETAILED DESCRIPTION

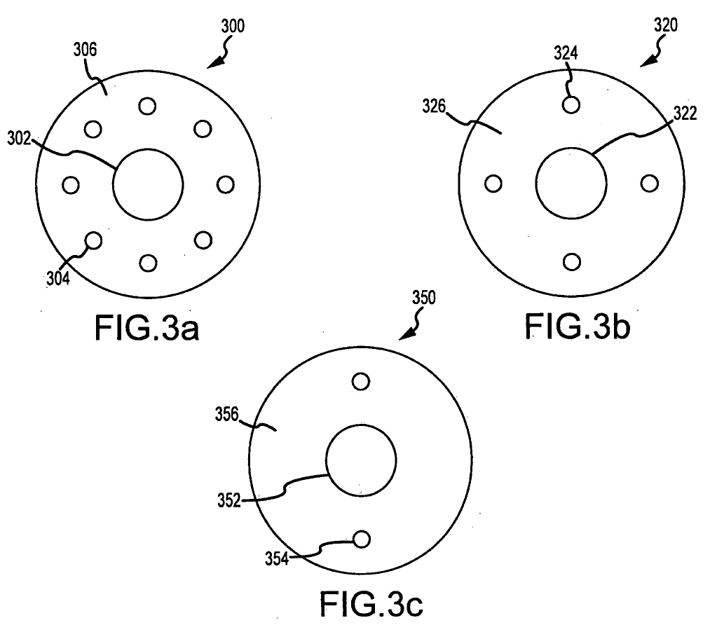

Embodiments of the present invention are directed to methods and systems for providing PTHs in PCBs, which advantageously allow improved soldering capabilities. Such methods and systems are achieved by reducing the heat sinking effects of PTHs by providing one or more vias surrounding the PTHs to provide an electrical connection between the PTH and the bottom layer of a PCB. In this regard, the PTHs may not directly contact internal ground or power layers, or may contact fewer ground or power layers, so the heat sinking effects are reduced. This feature enables molten solder to fill substantially the entire PTH before freezing. Various features and embodiments of the present invention are described in detail below with reference to FIGS. 3-6.

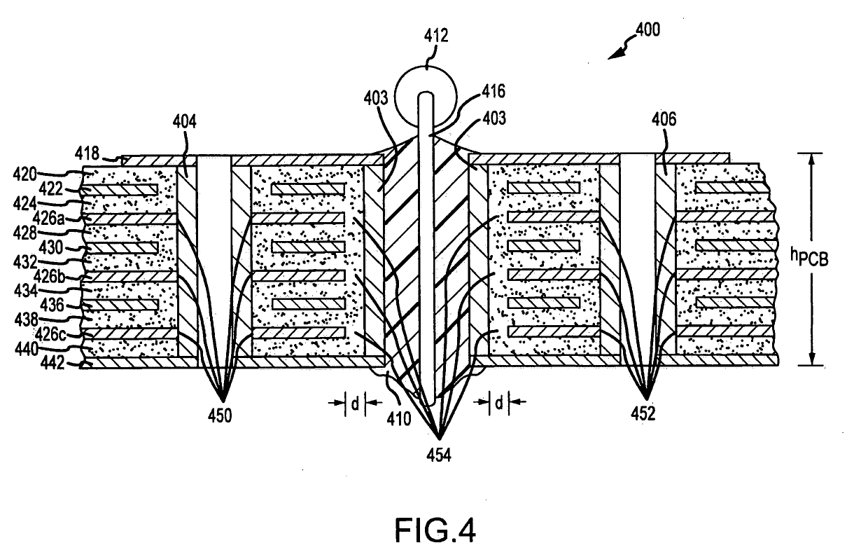

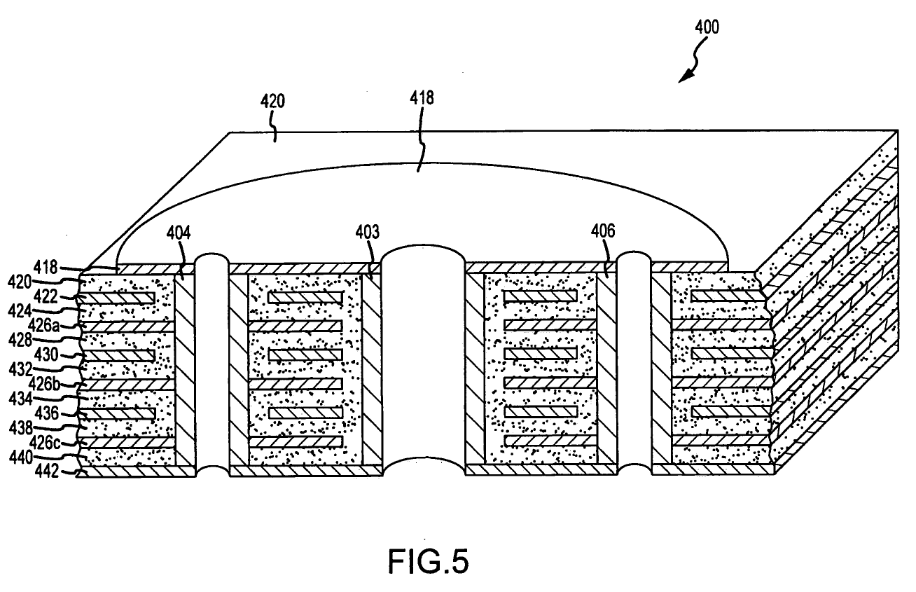

FIGS. 3a-3c illustrate top views of various embodiments of exemplary “ring of power” vias (or PTH assemblies) 300, 320, and 350 of the present invention. FIG. 3a illustrates a PTH 302 that is surrounded by eight plated vias 304. The PTH 302 is electrically coupled to the vias 304 by a conductive layer 306 that may be disposed, for example, over the top layer of a PCB. For example, the conductive layer 306 may be metallic pad (e.g., a surface land) printed on the surface of a PCB and coupled to the PTH 302. The PTH 302 may be used to couple a pin of an electronic device (e.g., a resistor, a transistor, an integrated circuit, or the like) on the top layer of a PCB to an electrical connection on the bottom layer of the PCB. Advantageously, the PTH 302 is not connected to any internal layers on the PCB, but rather, the eight vias 304 are utilized to couple the PTH 302 to the bottom conductive layer of a PCB through the conductive layer 306 (see FIGS. 4 and 5 and related description). In this regard, a relatively low amount of heat is transferred away from the PTH 302 when molten solder fills it during the soldering process, thereby allowing the molten solder to substantially fill the PTH 302 without prematurely freezing.

FIG. 3b illustrates another “ring of power” via 320 which includes a PTH 322 which is surrounded by four vias 324. The vias 324 and the PTH 322 are coupled together through a conductive layer 326. Similarly, another “ring of power” via 350 is shown in FIG. 3c that includes a PTH 352, two vias 354, and a conductive layer 356.

It should be appreciated that the embodiments shown in FIGS. 3a-3c are mere examples, and that other numbers of vias may be provided. Further, the size and shape of the PTHs and the vias may be configured to suit a particular application. For example, in applications which require a relatively large amount of current flow, the relative number of vias surrounding a PTH may be increased to account for this factor. Other relevant factors may include PCB thickness, the number of layers that are to be coupled to the vias, thickness of the copper plating for the PTH and/or the vias, or any other factors. As an example, in one embodiment, a PTH has a hole diameter of about 80 to 100 mils, while the surrounding vias have a hole diameter of about 15 to 25 mils. As can be appreciated, any suitable hole diameter for the PTH and vias may be used to suit a particular application.

FIGS. 4 and 5 illustrate two cross-sectional views of an exemplary PCB 400 that includes a “ring of power” via As shown the “ring of power” via includes a PTH 403, two vias 404 and 406 (similar to the “ring: of power” via 350 shown in FIG. 3c), and a conductive surface land 418. The PCB 400 includes signal layers 422, 430, and 436, ground layers 426a-c and 442, and dielectric layers 420, 424, 428, 432, 434, 438, and 440 disposed between the various conductive layers. Typically, the conductive layers are made of copper, but other conductive material may be used. Further, the dielectric layers may be made of epoxy resin (e.g., FR4), polyimide, polytetrafluoroethylene (PTFE), or any other suitable dielectric material.

In the example shown in FIG. 4, a pin 416 of a resistor 412 is to be coupled to ground potential. To achieve this, the PTH 403 is coupled to the vias 404 and 406 through the surface land 418, and the vias 404 and 406 are in turn coupled to the internal ground layers 426a-c (e.g., at the points 450 for the via 404 and at the points 452 for the via 406). That is, the PTH 403 is not directly coupled to the internal ground layers 426a-c (as shown by the spaces 454, which show that the ground layers 426a-c are spaced apart from a sidewall of the PTH 403 by a distance “d”), but only indirectly through the plated vias 404 and 406 by way of the surface land 418. As noted above, often the ground (or power) layers may be large, continuous sheets of copper. Thus, to ensure that the internal ground layers 426a-c do not contact the PTH 403, the copper sheets may include patterned holes having a diameter that is greater than the outer diameter of the PTH 403. These patterned holes may generally be referred to as clearance holes, or anti-pads.

By not directly coupling the PTH 403 to the internal ground layers, the PTH 403 has relatively low heat transfer characteristics. This feature permits molten solder 410 to “wick” up through the PTH 403 to substantially fill the entire PTH 403 during the soldering process. As a result, the electrical and mechanical connections between the pin 416 and the associated PCB are relative secure.

It should be appreciated that although the embodiment shown in FIGS. 4 and 5 show the PTH 403 as not being connected to any of the internal ground layers 426a-c, other PTHs may be provided to connect pins to power layers or signal layers. As noted above, typical multilayered PCBs may have multiple ground and power layers (e.g., 4 layers, 8 layers, 12 layers, or more) that are essentially copper sheets that may conduct a relatively large amount of heat. Therefore, the “ring of power” vias described herein may more helpful when used with power and/or ground connections. Further, as the height of a PCB (_{PCB}) increases (e.g., over 50 mils, over 100 mils, or more), the features of the present invention may be increasingly beneficial.

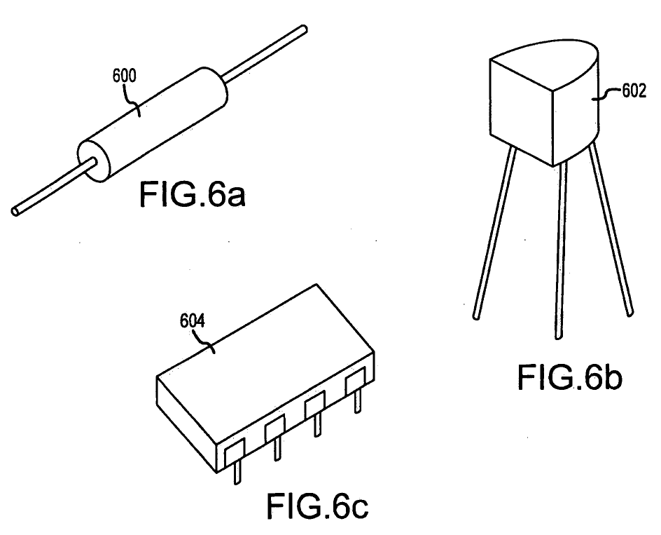

FIGS. 6a-6c illustrate various electronic components that include pins that may be coupled to a PCB using PTH technology. More specifically, FIG. 6a shows a resistor 600; FIG. 6b shows a transistor 602; and FIG. 6c shows an integrated circuit 604. As can be appreciated, various other electronic components may also be used in a PCBA that incorporates the “ring of power” vias described herein.

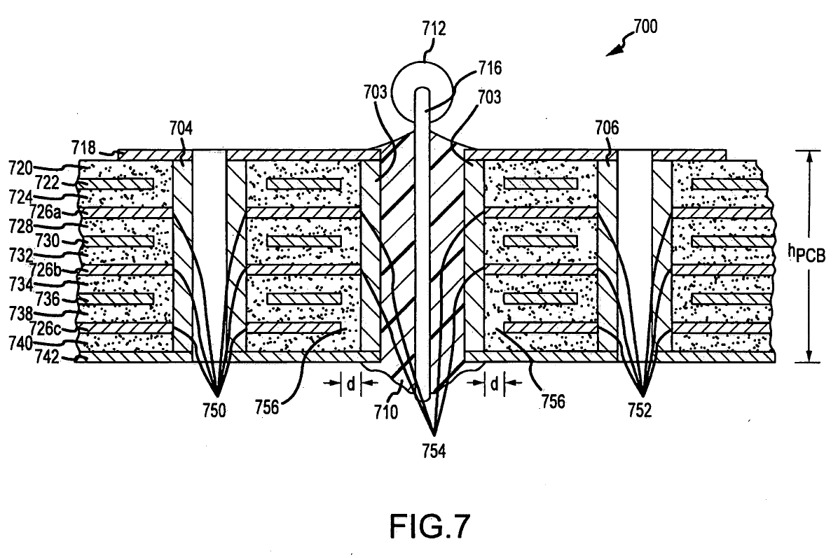

FIG. 7 illustrates a cross-sectional view of an exemplary PCB 700 that includes a “ring of power” via As shown the “ring of power” via includes a PTH 703, two vias 704 and 706 (similar to the “ring of power” via 350 shown in FIG. 3c), and a conductive surface land 718. The PCB 700 includes signal layers 722, 730, and 736, ground layers 726a-c and 742, and dielectric layers 720, 724, 728, 732, 734, 738, and 740 disposed between the various conductive layers.

In the example shown in FIG. 7, a pin 716 of a resistor 712 is to be coupled to ground potential. To achieve this, the PTH 703 is coupled to the vias 704 and 706 through the surface land 718 and the ground layers 726a-b (as shown by the points 754 at the intersection of a sidewall of the PTH 703 and the ground layers 726a-b), and the vias 704 and 706 are in turn coupled to the internal ground layers 726a-c (e.g., at the points 750 for the via 704 and at the points 752 for the via 706). That is, the PTH 703 is not directly coupled to the internal ground layer 726c (as shown by the spaces 756 having a width “d”), but only indirectly through the plated vias 704 and 706 by way of the surface land 718, and the ground layers 726a-b. As noted above, often the ground (or power) layers may be large, continuous sheets of copper. Thus, to ensure that the internal ground layer 726c does not contact the PTH 703, the copper sheets may include patterned holes having a diameter that is greater than the outer diameter of the PTH 703, such that the ground layer 726c is spaced apart from the sidewall of the PTH 703 by a distance “d”. These patterned holes may generally be referred to as clearance holes, or anti-pads.

By not directly coupling the PTH 703 to the internal ground layer 726c, the PTH 703 has relatively lower heat transfer characteristics. This feature permits molten solder 710 to “wick” up through the PTH 703 to substantially fill the entire PTH 703 during the soldering process. As a result, the electrical and mechanical connections between the pin 716 and the associated PCB are relative secure.

It should be appreciated that although the embodiment shown in FIG. 7 show the PTH 703 as not being connected to the internal ground layer 726c, other configurations are contemplated. For example, any number of internal conductive layers (e.g., one layer, more than one layer, all internal layers, or the like) may be spaced apart from a PTH to reduce the heat transfer characteristics to a level that it suitable for a particular soldering process.

While the invention has been illustrated and described in detail in the drawings and foregoing description, such illustration and description is to be considered as exemplary and not restrictive in character. For example, certain embodiments described hereinabove may be combinable with other described embodiments and/or arranged in other ways (e.g., process elements may be performed in other sequences). Accordingly, it should be understood that only the preferred: embodiment and variants thereof have been shown and described and that all changes and modifications that come within the spirit of the invention are desired to be protected.

I claim:

1. A multi-layer printed circuit board (PCB) comprising:
a plurality of conductive layers with dielectric material: disposed therebetween;
a through-hole that extends through the PCB; and
a via, spaced apart from the through-hole, electrically coupled to one or more internal conductive layers of the plurality of conductive layers;
wherein the through-hole is electrically coupled to the via, and wherein the through-hole is spaced apart from at least one of the one or more internal conductive layers.

2. The multi-layer PCB of claim 1, further comprising a surface land that couples the through-hole to the via.

3. The multi-layer PCB of claim 1, wherein the through-hole is plated with copper.

4. The multi-layer PCB of claim 1, wherein the via is plated with copper.

5. The multi-layer PCB of claim 1, wherein the one or more internal conductive layers are ground layers or power layers.

6. The multi-layer PCB of claim 1, wherein the one or more internal conductive layers includes at least two layers, and wherein the through-hole is spaced apart from at least two of the internal conductive layers.

7. The multi-layer PCB of claim 1, wherein the via is a first via, the multi-layer PCB further comprising:
a second via, spaced apart from the through-hole, electrically coupled to the one or more internal conductive layers of the plurality of conductive layers;
wherein the through-hole is electrically coupled to the second via.

8. A method of manufacturing a PCB, the method comprising:
providing a multi-layer PCB that includes a plurality of conductive layers with dielectric material disposed therebetween;
generating a through-hole that extends through the PCB; and
generating a via, spaced apart from the through-hole, that is electrically coupled to one or more internal conductive layers of the plurality of conductive layers;
wherein the through-hole is electrically coupled to the via, and wherein the through-hole is spaced apart from at least one of the one or more internal conductive layers.

9. The method of claim 8, further comprising:
providing a surface land that couples the through-hole to the via.

10. The method of claim 8, wherein the through-hole is plated with copper.

11. The method of claim 8, wherein the via is plated with copper.

12. The method of claim 8, wherein the one or more internal conductive layers are ground layers or power layers.

13. The method of claim 8, wherein the one or more internal conductive layers includes at least two layers, and wherein the through-hole is spaced apart from at least two of the internal conductive layers.

14. The method of claim 8, wherein the via is a first via, the method further comprising:
generating a second via, spaced apart from the through-hole, that is electrically coupled to the one or more internal conductive layers of the plurality of conductive layers, wherein the through-hole is electrically coupled to the second via.

15. A method for mechanically coupling an electrical component to a multi-layer PCB, the method comprising:
providing a multi-layer PCB that includes:
a plurality of conductive layers with dielectric material disposed therebetween;
a through-hole that extends through the PCB; and
a via, spaced apart from the through-hole, electrically coupled to one or more internal conductive layers of the plurality of conductive layers;
wherein the through-hole is electrically coupled to the via, and wherein the through-hole is spaced apart from at least one of the one or more internal conductive layers;
providing an electrical component that includes a pin;
positioning the pin of the electrical component into the through-hole of the PCB; and
soldering the pin to the through-hole to form a secure mechanical and electrical connection, wherein the solder substantially fills the through-hole.

16. The method of claim 15, wherein the soldering is performed by a wave soldering process.

17. The method of claim 15, wherein the. PCB further comprises a surface land that couples the through-hole to the via.

18. The method of claim 15, wherein the through-hole and the via are plated with copper.

19. The method of claim 15, wherein the one or more internal conductive layers of the PCB are ground layers or power layers.

20. The method of claim 15, wherein the one or more internal conductive layers includes at least two layers, and wherein the through-hole is spaced apart from at least two of the internal conductive layers.
